(19) United States
(12) Patent Application Publication
(10) Pub. No.: US 2013/0120957 A1
(43) Pub. Date: May 16, 2013

(54) RF SHIELDING FOR ELECTRONIC COMPONENTS

(71) Applicant: Apple Inc., Cupertino, CA (US)

(72) Inventors: Christopher Matthew Werner, San Jose, CA (US); Fletcher R. Rothkopf, Los Altos, CA (US); Stephen Brian Lynch, Portola Valley, CA (US); Dennis R. Pyper, Cupertino, CA (US); Wyeman Chen, Heyward, CA (US); Michael M. Nikkhoo, Saratoga, CA (US); Amir Salehi, San Jose, CA (US)

(73) Assignee: APPLE INC., Cupertino, CA (US)

(21) Appl. No.: 13/631,216

(22) Filed: Sep. 28, 2012

Related U.S. Application Data
(60) Provisional application No. 61/559,865, filed on Nov. 15, 2011.
(60) Provisional application No. 61/563,464, filed on Nov. 23, 2011.

(51) Int. Cl. H05K 9/00; H05K 3/34; H05K 3/30

(52) U.S. Cl. 361/818; 29/834; 29/832; 29/840; 174/382

(57) ABSTRACT

An RF shield formed of RF opaque material that permits access to components on a printed circuit board is described. The RF shield can include a first portion attached to the PCB and a removable top portion attached to the first portion at an interface. The top portion is removed from the first portion to expose the components on the PCB. In one aspect of the described embodiment, the top portion is peeled away from the first portion. The components are enclosed within the RF shield after the removal of the top portion by attaching and sealing another top portion to the first portion at the interface by, for example, laser attaching the first portion and the other top portion at the interface.

### CROSS-REFERENCE TO RELATED APPLICATIONS

This application claims the benefit of prior filed U.S. Provisional Patent Application No. 61/559,865, filed Nov. 15, 2011, and of prior filed U.S. Provisional Patent Application No. 61/563,464, filed Nov. 23, 2011, each of which is incorporated by reference herein in its entirety.

### TECHNICAL FIELD

The present invention relates generally to assembly of electronic products. More particularly, a method and an apparatus are described for providing radio frequency (RF) shielding for electronic components soldered to or otherwise attached to a printed circuit board, or PCB. Specific embodiments describe a low profile RF shielding structure some of which can provide for defective component rework.

### BACKGROUND OF THE INVENTION

During the assembly of many electronic products, various components must be attached to a printed circuit board. Generally, the components are attached at contact pads that act as both a support structure and an electrical connection to electrical traces incorporated into the printed circuit board. Generally, the component includes a number of connection tabs, or pins, that can, for example, be solder connected to the electrical connection, also referred to as a pad. Generally, the pads are formed of thin conductive material such as aluminum or copper that forms a good bond with the solder that is generally applied during what is referred to as a solder reflow operation.

In order to provide appropriate RF shielding, a metal shield can is attached (usually using solder) onto the printed circuit board in such a way that the metallic can covers the components forming what is referred to as a Faraday Cage that may prevent high frequency RF noise from interfering with the bulk system of an electronic device. However, once the component is attached and electrically connected to the appropriate contact pads and the shield can is in place, either the component or the assembled product (or single PCB, if needed) is functionally tested. If the functional testing proceeds successfully, the component, PCB, or electronic product can advance to the next step in the manufacturing process. However, if the functional testing fails, then it may be necessary to remove the faulty component (if that is in fact what is causing the failure) or at least provide access to the faulty component. Unfortunately, in order to release, or rework, the faulty component, the faulty component must first be exposed which can be difficult due to the presence of the RF shield. In addition, the additional space taken up by the presence of the RF shield can reduce that space that would otherwise be available for components.

Thus there exists a need for a method and an apparatus for providing an improved RF shield.

### SUMMARY OF THE DESCRIBED EMBODIMENTS

An RF shield formed of RF opaque material that permits access to components on a printed circuit board (PCB), the RF shield attached to the PCB and enclosing a portion of the PCB on which is mounted at least one electronic component, the enclosed portion of the PCB being RF isolated is described. The RF shield includes at least a fence secured to the PCB and a reduced thickness lid conductively attached to the fence. In the described embodiment, the reduced thickness lid includes at least a layer of metal having a thickness in a range of about 0.009 or 0.010 millimeters to 0.050 millimeters, wherein a clearance between a bottom surface of the layer of metal and at the least one electronic component is within a range of 0.0 millimeters to about 0.010 millimeters. The layer of metal can be aluminum, copper, and so forth.

In another embodiment, a method of assembly is described. The method of assembly is carried out by performing at least the following operations: providing a printed circuit board, the printed circuit board having at least one electronic component mounted thereon, securing a conductive fence to the printed circuit board, the conductive fence surrounding the at least one component, and RF isolating the at least one electronic component by conductively attaching a reduced thickness lid to the fence. In the described embodiment, the reduced thickness lid includes at least a layer of metal having a thickness in a range of about 0.009 millimeters to 0.050 millimeters and a clearance between a bottom surface of the layer of metal and at the least one electronic component is within a range of 0.0 millimeters to about 0.010 millimeters.

In some other embodiments, there may be provided an EMI shield formed of RF opaque material that may permit access to a component on a printed circuit board. The EMI shield can include a first portion attached to the PCB and a removable top portion attached to the first portion at an interface. The top portion may be removed from the first portion to expose the component on the PCB. The top portion may be peeled away from the first portion. The component may be enclosed within the EMI shield after the removal of the top portion by attaching and sealing another top portion to the first portion at the interface by, for example, laser attaching the first portion and the other top portion at the interface.

In some other embodiments, there may be provided a method that may include attaching a first portion of a shield assembly to a circuit board. The method may also include, after the attaching, removing a second portion of the shield assembly from the first portion of the shield assembly. The method may also include, after the removing, coupling a new portion of the shield assembly to the first portion of the shield assembly. In some embodiments, for example, the coupling may include laser welding. In some embodiments, for example, the removing may include peeling the second portion away from the first portion. In some embodiments, for example, the removing may include breaking a joint between the first portion and the second portion. In some embodiments, for example, the attaching may include attaching the first portion of the shield assembly to the circuit board about an electronic component, and the removing may include exposing the electronic component for re-work. In some embodiments, for example, the attaching may include soldering the first portion of the shield assembly to the circuit board.

In some other embodiments, there may be provided an assembly that may include a first portion configured to be attached to a mounting surface, a second portion removably coupled to the first portion, and a third portion configured to be attached to the first portion once the second portion is removed for shielding a component on the mounting surface. In some embodiments, for example, at least one of the first portion, the second portion, and the third portion may include RF opaque material. In some embodiments, for example, the second portion may be removably coupled to the first portion at an easily broken joint. In some embodiments, for example, the third portion may be configured to be welded to the first portion. In some embodiments, for example, the first portion may include a top and at least one side extending from the top to a free side end, the free side end of the at least one side may be configured to be attached to the mounting surface, the second portion may be removably coupled to the top of the first portion, and the third portion may be configured to be attached to the top of the first component once the second portion is removed. In such embodiments, the top of the first portion may include an opening therethrough, the opening may be covered by the second portion when the second portion is coupled to the first portion, and the opening may be exposed once the second portion is removed. In such embodiments, the opening may be covered by the third portion once the third portion is attached to the first portion. In such embodiments, the opening may expose the component for re-work once the second portion is removed.

### BRIEF DESCRIPTION OF THE DRAWINGS

The invention and the advantages thereof may best be understood by reference to the following description taken in conjunction with the accompanying drawings.

FIG. 1 shows a representative printed circuit board or (PCB) system 100 in accordance with the described embodiments.

FIG. 2 shows a cross sectional view of a representative RF shield shown in FIG. 1.

FIG. 3 shows a representative double sided PCB system in accordance with the described embodiments.

FIG. 4 shows the cross section of the PCB system shown in FIG. 2 highlighting the cross section of a lid/fence interface.

FIGS. 5A and 5B show additional embodiments of a reduced thickness lid.

FIG. 6 shows a PCB system highlighting another embodiment of an RF shield in the form of reduced footprint RF shield.

FIG. 7 shows a PCB system in accordance with the described embodiments.

FIG. 8 shows a lid having perforations located in a peripheral region of the lid.

FIGS. 9A and 9B show another embodiment of a reduced thickness lid in the form of a flexible lid having a top surface on which is mounted a plurality of conductive strips.

FIG. 9C shows a representative cross section of the reduced thickness lid of FIGS. 9A and 9B illustrating a manner in which the reduced thickness lid is conductively attached to a fence.

FIG. 10 shows a cross section of a PCB system in which a lid of an RF shield is connected to chassis ground.

FIG. 11 shows a flowchart describing a process in accordance with the described embodiments.

FIG. 12 shows a representative removable RF shield anchored to a PCB in accordance with the described embodiments.

FIG. 13 shows a PCB system on which is mounted an RF shield having a removable lid.

FIG. 14 shows a flowchart describing a process in accordance with the described embodiments.

### DETAILED DESCRIPTION OF EXAMPLE EMBODIMENTS

In the following description, numerous specific details are set forth to provide a thorough understanding of the present invention. It will be apparent, however, to one skilled in the art that the present invention may be practiced without some or all of these specific details. In other instances, well known process steps have not been described in detail in order to avoid unnecessarily obscuring the present invention.

An RF shield can be used to provide RF isolation to components mounted to a printed circuit board (PCB) whose proper operation can be adversely affected by interference with RF noise, also referred to as EMI or electromagnetic interference. Moreover, in addition to protecting components within an electronic device from EMI from an external RF source, the RF shield can also prevent RF energy generated by components within the electronic device from leaking out of and interfering with other components within the electronic device (but outside of the RF shield) as well as with other RF sensitive components or circuits external to the electronic device.

Some RF shields generally take the form of a metal enclosure attached to the PCB using, for example, solder. The metal enclosure may be generally “thick” walls to support the RF shield and provide a good anchor to attach to the PCB. In order to span a relatively long distance across the PCB and withstand an impact event without bending or warping (possibly resulting in damage to at least some of the enclosed components on the PCB), the top portion may be formed of a thick layer of metal. Unfortunately, the presence of a thick layer of metal as the top portion may increase the overall weight of the RF shield. Furthermore, in order to assure that any bending of the top portion (be it from an impact or natural deformation over time) may not damage the enclosed components, the clearance between the top portion and any enclosed component must be no less than a pre-determined distance. In this way, the conventional RF shield can add excess weight to the PCB (which in small form factor electronic devices can be noticeable) as well as take up a significant amount of valuable PCB real estate requiring that the PCB be of an appropriate size.

In contrast, some embodiments herein describe an RF shield well suited for use with a printed circuit board in a computing device. The computing device can take many forms. For example, the computing device can take the form of a desktop computer or the computing device can have a small form factor such as a tablet computer. In any case, the embodiments of the RF shield described herein may provide a space and weight efficient system for providing EMI isolation to RF sensitive components mounted to a PCB within a computing device. Some of the advantages of the described embodiments include may the innovative RF shield having a reduced overall footprint (i.e., reduced thickness, or Z stack), reduced weight, easy access to components for re-work, and in some embodiments may provide for additional ground plane. It should be noted that the reduction in RF shield footprint can also reduce the size and weight of the PCB as well as increase the PCB component density.

In one embodiment, the RF shield can include a fixed first portion (also referred to as a fence) secured to the PCB. The fence may generally be secured to the PCB using solder. Solder secures the fence to the PCB but also provides a path between the fence and conductive traces associated with the PCB. Accordingly, the fence may be formed of a material (such as metal) capable of providing mechanical support for the RF shield during an expected operational life of the computing device as well as providing a suitable base for forming a soldered connection to the PCB.

The RF shield may also include a reduced thickness top portion (also referred to as a lid) having a size and shape in accordance with the fence such that the lid may match the profile of the fence. By reduced thickness, it is meant that instead of having a thickness of about 0.150 millimeters that may be typical of the lid of conventional RF shields, the lid in the described embodiments may have a nominal thickness in the range of about 0.009 millimeters or 0.010 millimeters to 0.050 millimeters. Furthermore, the reduced thickness of the lid may allow a reduced clearance between the lid and the underlying components. In fact, due to the ability of the thinner lid to conform around the peaks of any component in which it comes in contact, the nominal clearance between the lid and the “tallest” component can be on order of 0.0 millimeters to about 0.010 millimeters since the risk of damage is minimal. The lid can be formed of a strong and resilient metal such as stainless steel. The lid can be conductively attached to the fence to form the desired EMI containment structure. In one embodiment, the lid can be conductively attached to the fence using any number of techniques, such as welding (e.g., laser spot welding) or soldering. In some embodiments, the RF shield can be assembled and then attached to the PCB after all components have been attached and functionally tested. The RF shield can also be assembled by first attaching the fence to the PCB followed by attaching the lid to the fence (either before or after the components have been functionally tested).

In some embodiments, a plurality of perforations can be formed on a perimeter of the lid. In order to preserve the RF shielding capability of the RF shield, the perforations can be sized less than a wavelength of the expected electromagnetic radiation. In other words, since the size of the perforations may be smaller than the wavelength of the electromagnetic radiation most of the associated RF energy cannot pass through the perforations, thereby preserving the effectiveness of the Faraday cage that may be formed by the RF shield. In some cases, the perforations can facilitate easy removal of the lid to provide access to components therein.

In other embodiments, the lid can be flexible. The flexible lid can be formed of similar material and manufactured in much the same way as the printed circuit board along the lines of a polyimide. For example, copper (or any other conductive material) can be deposited onto a polyimide base layer and etched away to form a plurality of conductive traces on a surface of the polyimide base layer in any suitable arrangement. In one embodiment, the copper layer can be approximately 0.009 millimeters thick and may be arranged in a cross hatched pattern on the surface of the polyimide layer. In order to preserve the RF shielding properties of the lid, the trace width and a pitch between the traces can be in accordance with the wavelength of the electromagnetic radiation to be blocked. In this way, the conductive grid and polyimide base layer can act as a flexible and effective RF shield.

In some cases, the flexible lid can have flexible base layer (such as polyimide) having a top surface with conductive traces in a central region and conductive pads formed on a peripheral region. The solder pads can, in turn, coincide with a solder pad on a bottom surface of the flexible base layer. The solder pads on the top surface and the bottom surface can each be aligned with a through hole or via that extends between the top and bottom surfaces of the flexible base layer. Solder can be used to electrically connect the conductive grid to the contact pads on the top surface some of which may flow through the via to make electrical contact with the corresponding contact pad on the bottom surface. The contact pad on the bottom surface can, in turn, be electrically connected to a chassis ground by way of the conductive fence. In this way, the conductive grid on the top surface of the flexible lid (or a conductive pattern optionally formed on the bottom surface of the flexible lid) can be electrically connected to the chassis ground, which may improve the overall capability of the RF shield to prevent transmission of RF energy.

It should be noted that by applying a suitable amount of heat, the flexible lid can be removed to provide access to electrical components therein. In some cases, the solder used to attach the flexible lid to the fence can be a lower temperature solder than that used to solder attach the fence to the PCB. In this way, since the lower temperature solder melts at a lower temperature than the higher temperature solder, it is highly unlikely that heat applied to the flexible lid/fence interface sufficient to melt the low temperature solder to attach the flexible lid to the fence (or heat applied to remove the flexible lid from the fence) will cause any melting of the higher temperature solder even though the fence is a good thermal conductor.

In yet another embodiment, the RF shield may include a second removable portion attached to the fence at an interface. The interface can take the form of a joint that can be easily broken by the application of a force having the effect of removing the lid from the fence. In one embodiment, the lid can be peeled back and away from the fence. In order to re-enclose the components on the PCB within the RF shield, another lid can be attached to the fence at the interface using a welding process. The welding process can include, for example, a laser welding process using a laser beam to weld the first fixed portion and the other removable portion at the interface. It should be noted that the laser beam can be derived from any number of lasing materials such as argon (Ar), CO₂, and so on.

Therefore the following discussion describes a method and apparatus for removing and re-attaching an RF shield to allow rework of components attached to the printed circuit board.

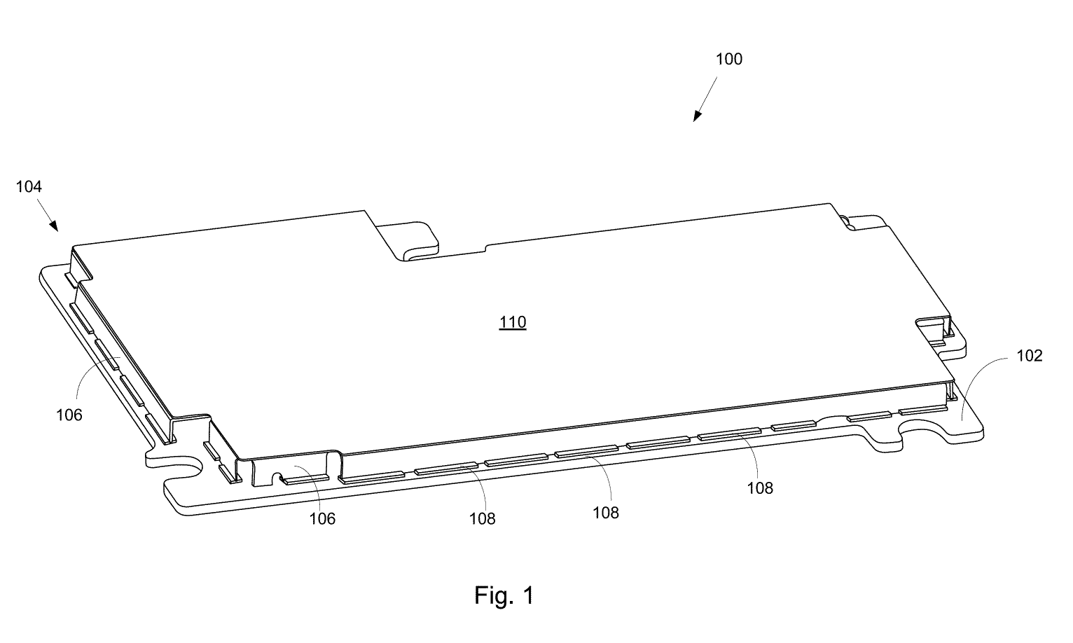

FIG. 1 shows representative printed circuit board or (PCB) system 100 in accordance with the described embodiments. PCB system 100 can be used to mechanically support and electrically connect electronic components using conductive pathways, tracks or signal traces etched from copper sheets laminated onto non-conductive substrate (such as polyimide) 102. Generally electronic components are attached to base layer (or substrate) 102 of PCB 100 using various techniques (such as soldering) to form a conductive bond between the electronic component and the signal traces within the substrate. Some components (such as integrated circuits) can be a significant source of electromagnetic (EM) radiation in the radio frequency portion of the electromagnetic spectrum. Electromagnetic interference (or EMI) is disturbance that affects an electrical circuit due to either electromagnetic induction or electromagnetic radiation emitted from the electronic component. The disturbance may interrupt, obstruct, or otherwise degrade or limit the effective performance of a circuit in proximity to the electronic component. These effects can range from a simple degradation of data to a total loss of data. In order to reduce or eliminate the EMI, an electromagnetic shield (also referred to as an RF shield) can be used to reduce the electromagnetic field by blocking the EM field with barriers made of conductive and/or magnetic materials. Such RF shielding is typically applied (1) to enclosures to isolate electrical devices from the ‘outside world’ and (2) to cables to isolate wires from the environment through which the cable runs.

As shown in FIG. 1, RF shield 104 can be used to isolate electrical devices mounted to PCB system 100 by forming what is known as a Faraday cage. A Faraday cage (or shield) is an enclosure formed by conducting material or by a mesh of such material. Such an enclosure blocks out external static and non-static electric fields. In order to form the requisite conductive enclosure, RF shield 104 can include fence 106 having at least a portion formed of conductive material such as metal. In those situations where fence 106 is subject to undergoing a solder operation, fence 106 can be formed of Ni or Ni based alloys or other solder friendly material. In any case, fence 106 can be conductively secured to substrate 102 of PCB 100 by plurality of pedestals 108. In the described embodiment, plurality of pedestals 108 can be soldered to conductive pads on substrate 102. In other embodiments, fence 106 can be secured to substrate 102 using conductive clips or, as described below, fence 106 can be edge mounted to substrate 102 further reducing the footprint of PCB system 100.

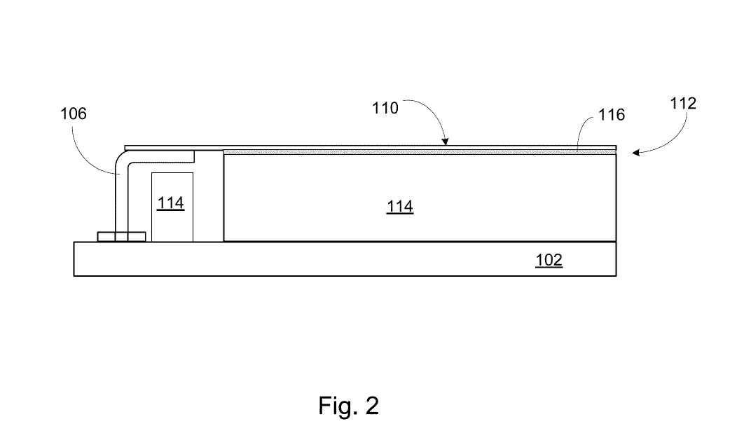

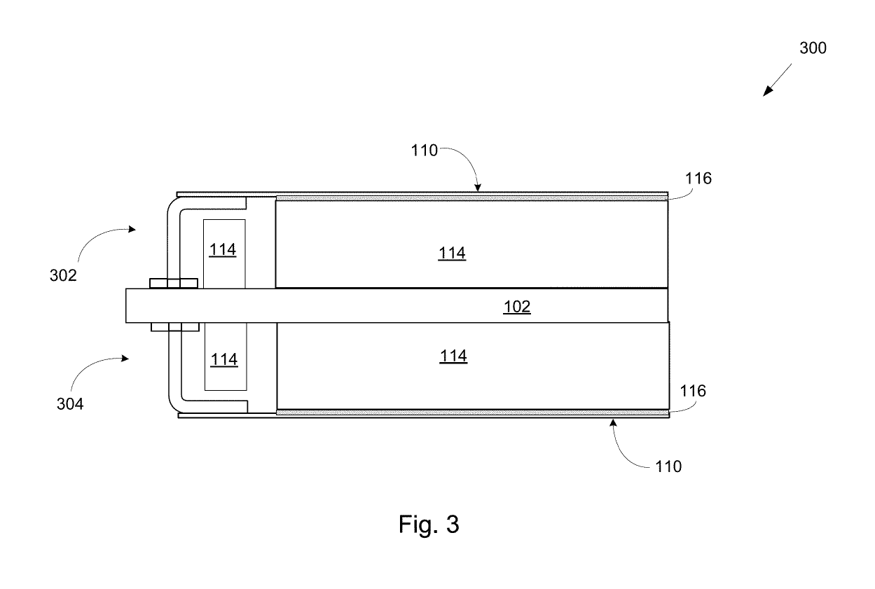

In any case, fence 106 can be secured to substrate 102 such that fence 106 remains anchored to substrate 102. In order to complete the conductive enclosure, RF shield 100 can include reduced thickness lid 110. Lid 110 can have a thickness on the order of about 0.009 or 0.010 millimeters to about 0.050 millimeters (compared to the conventional RF shield having a lid thickness of about 0.150 millimeters). In this way, lid 110 can take on characteristics typical of a foil. For example, lid 110 can be flexible. This foil like flexibility permits lid 110 to deform in such a way as to cover underlying components without causing damage. However, in order to assure that lid 110 maintains its structural integrity (such as not tearing or puncturing or corroding) over the course of the operating life of the electronic device in which PCB 100 resides, lid 110 can be formed of a strong and corrosion resistant material such as stainless steel. In this way, the flexibility and strength afforded lid 110 with the use of stainless steel, tolerances between lid 110 and any underlying component can be substantially reduced over that required for the conventional lid. For example, since lid 110 is both strong and flexible and is unlikely to be damaged or to damage any underlying component, even those it comes in contact with, clearance 112 between a bottom surface of lid 110 and underlying component 114 can range from as little as 0 millimeters to about 0.01 millimeters as shown in FIG. 2. In order to prevent unwanted electrical contact between component 114 and lid 110, insulating layer 116 can be placed between lid 110 and component 114. Insulating layer 116 can take the form of, for example, insulating tape. It should be noted that the typical clearance between a bottom surface of the lid and an underlying component with the conventional RF shield ranges from about 0.01 to 0.02 millimeters. In this way, the overall reduction in the Z stack of RF shield 104 when compared to the conventional RF shield can be about 0.160 millimeters. It should be noted, however, that as shown in FIG. 3 showing double sided PCB system 300, the total reduction in the Z stack of RF shield 302 and RF shield 304 can be doubled to about 0.320 millimeters.

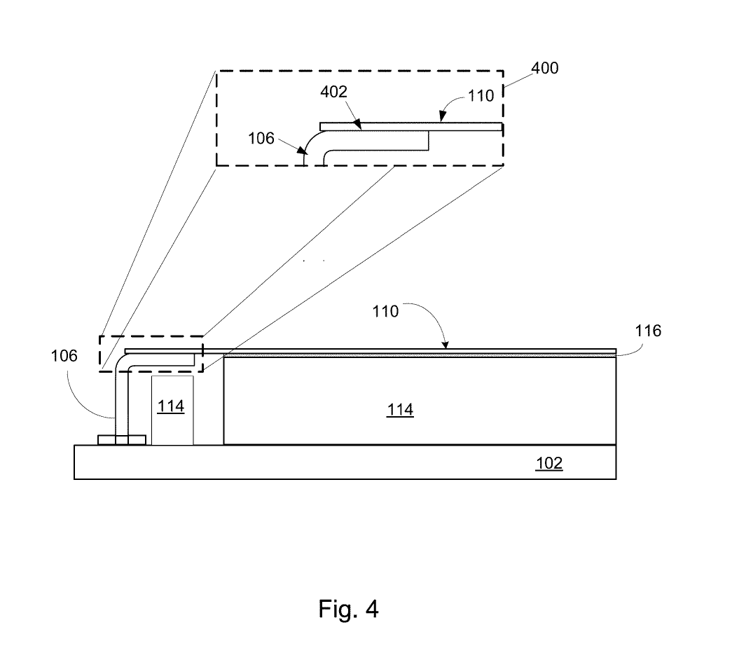

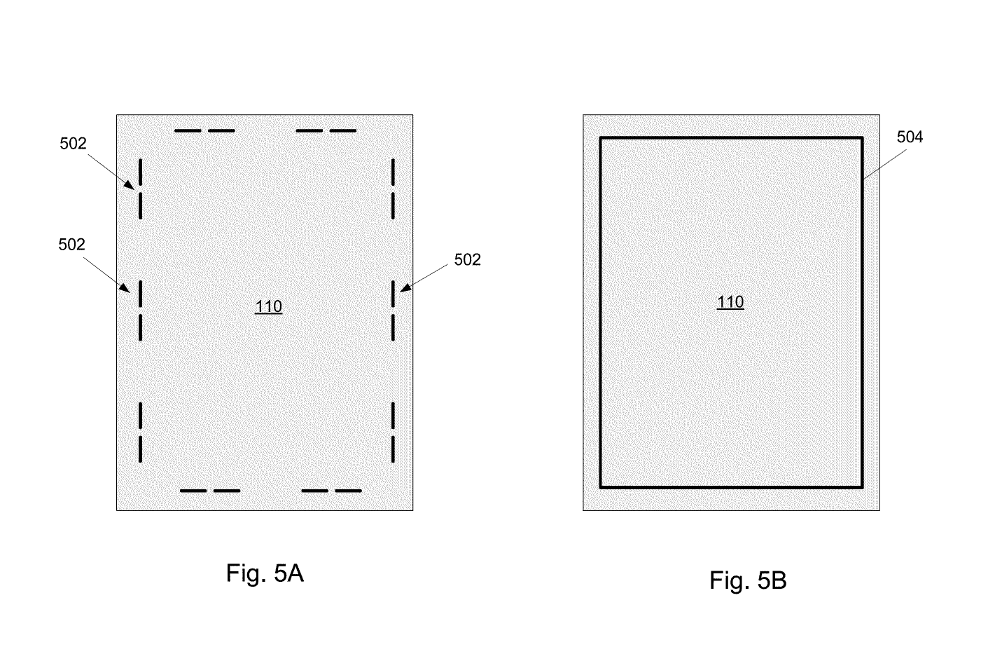

Lid 110 can be conductively attached to fence 106 in any number of ways depending upon the material from which lid 110 is made. For example, FIG. 4 shows the cross section of PCB system 100 shown in FIG. 2 highlighting cross section 400 of lid/fence interface 402. When lid 110 is formed of stainless steel, for example, fence 106 and lid 110 can be welded at lid/fence interface 402. However, when lid 110 is formed of metal less well suited for welding (or if a production environment is not well suited for conventional welding operations) other techniques such as laser welding or laser spot welding can be used. For example, as shown in FIG. 5A, lid 110 can be laser spot welded to fence 106 at selected ones of interface 402 shown as spot weld locations 502. In some cases, as shown in FIG. 5B, lid 110 can be laser welded in a more continuous fashion resulting in a continuous (or near continuous) laser weld 504. It should be noted that due to thermal considerations, it may be more advantageous to use a spot laser welding technique since less overall thermal energy is deposited during the laser spot welding operation than the continuous laser weld operation. In any case, the use of laser welding can be time and cost effective.

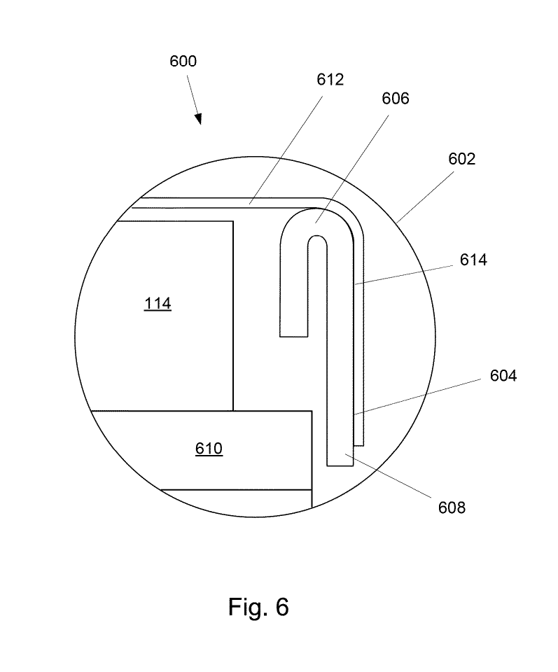

FIG. 6 shows PCB system 600 highlighting another embodiment of an RF shield in the form of reduced footprint RF shield 602. RF shield 602 can include fence 604 having upper portion 606 that is bent down in a U shape and bottom portion 608 that can be edge mounted to substrate 610. Moreover, due to its flexible foil like nature, lid 612 can be wrapped around and attached to upper portion 606 at lid/fence interface 614. In this way, amount of space and therefore the number and density of components within RF shield 602 can be increased. Moreover, the use of edge mounting can also reduce the overall dimensions of substrate 610 thereby reducing the footprint of PCB system 600.

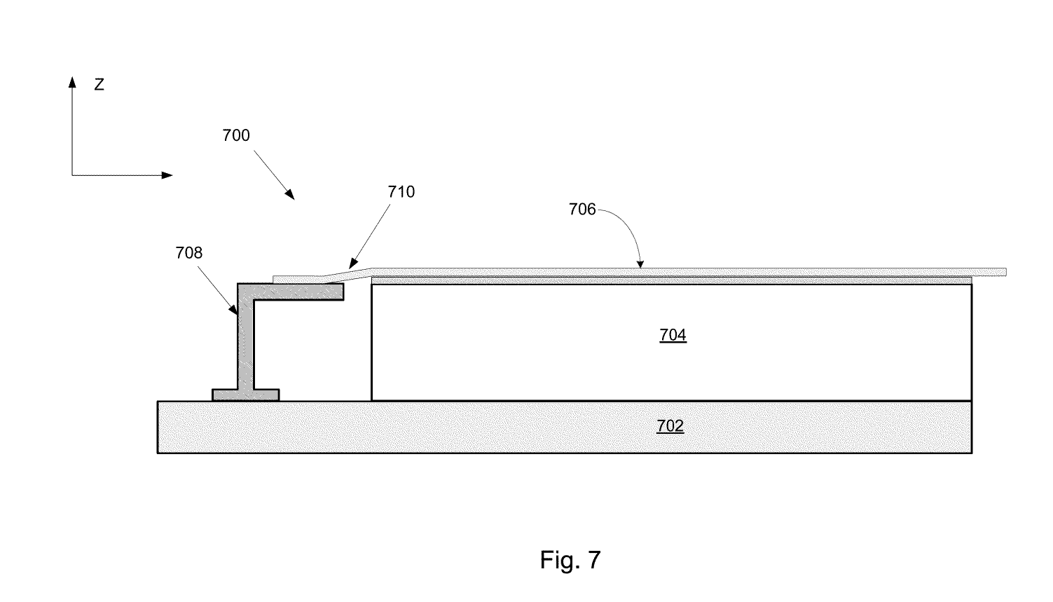

FIG. 7 shows PCB system 700 in accordance with the described embodiments. PCB system 700 includes substrate 702 on which is mounted components 704. It should be noted however, that by using reduced thickness lid 706, the foil like flexibility of lid 706 allows for at least some components to extend in the Z direction to a greater extent than does fence 708. Accordingly, the reduction of the size of fence 708 can reduce the overall weight of RF shield 710 as well as PCB system 700.

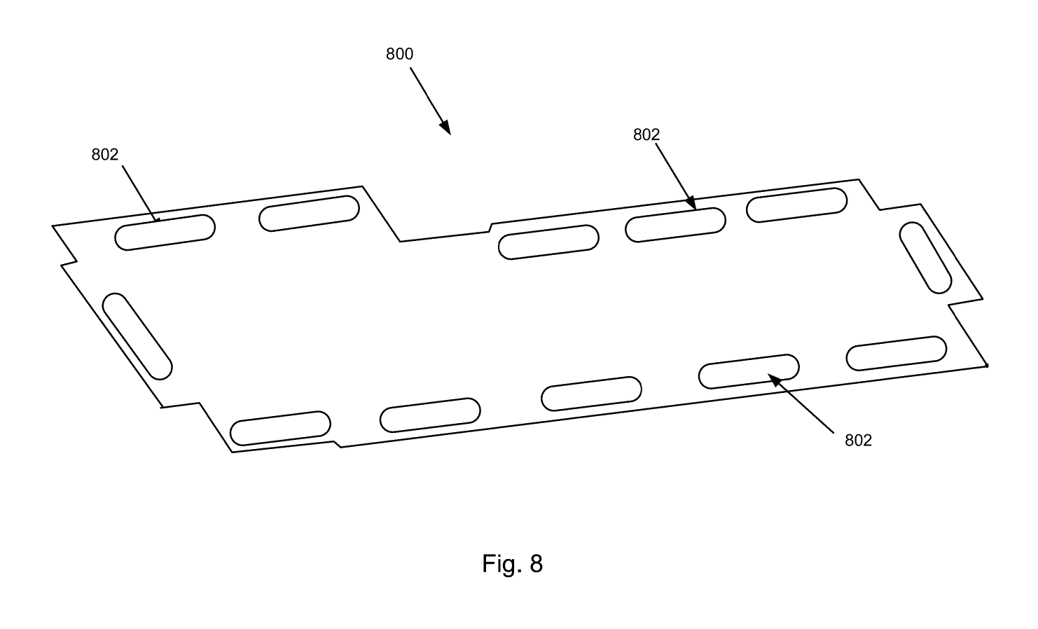

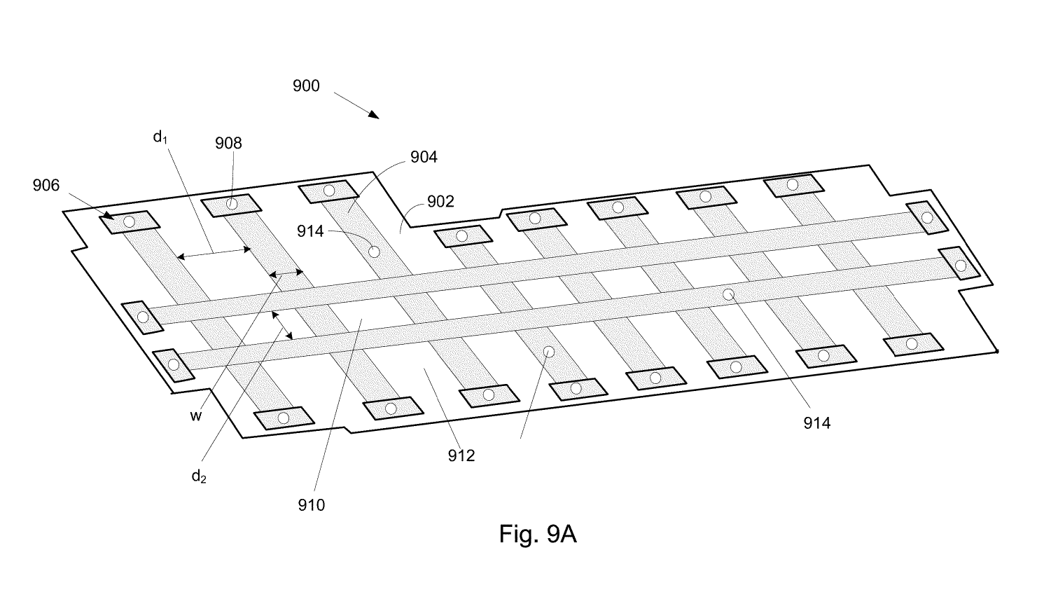

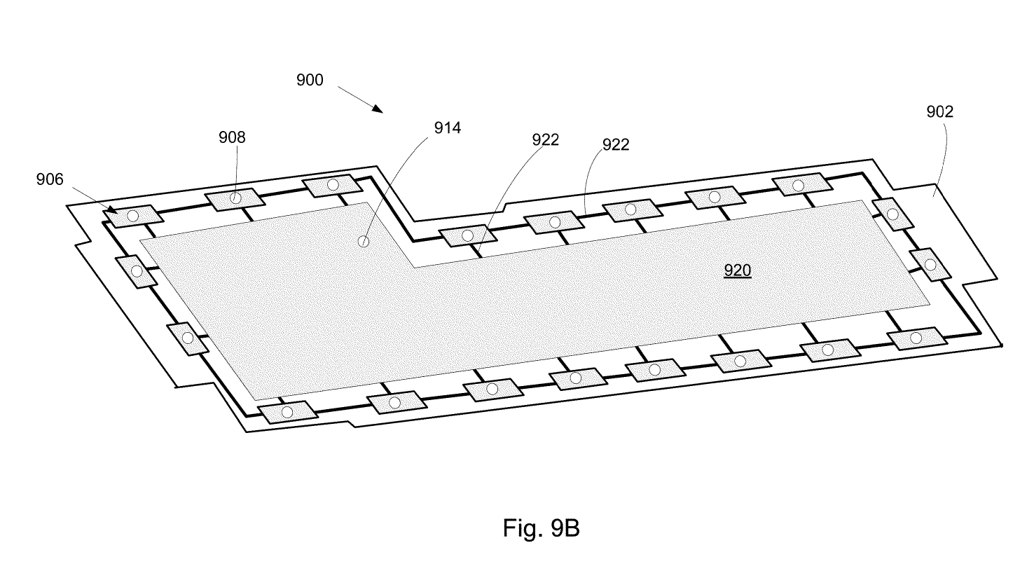

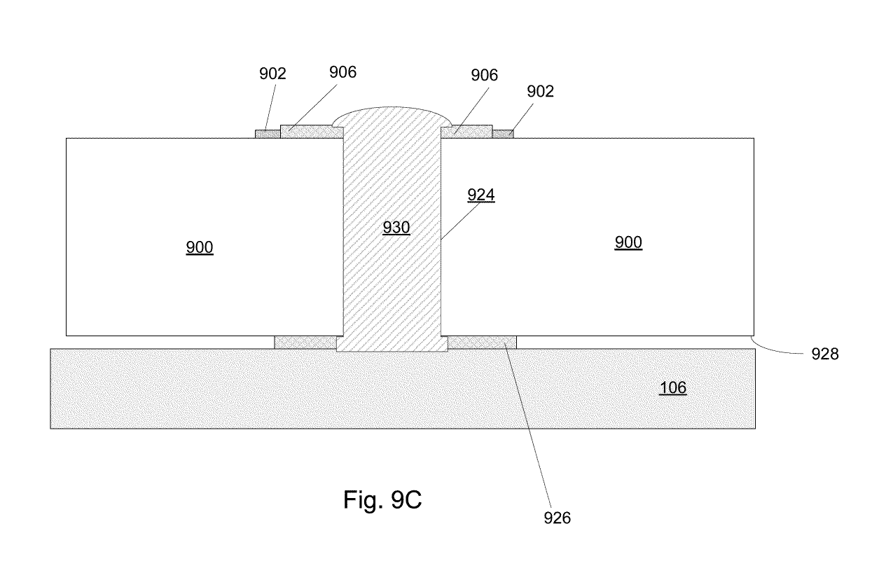

FIGS. 8 and 9A-9C show additional embodiments of a reduced thickness lid. For example, FIG. 8 shows lid 800 having a plurality of perforations 802 located in a peripheral region of lid 800. Since the dimensions of each perforation may be less than the wavelength of the electromagnetic radiation emitted by any underlying component, the effectiveness as an EM shield is essentially unaffected. Moreover, the presence of the perforations in lid 800 allows for easy removal of lid 800 in order to, for example, salvage components mounted to the PCB. In this and other embodiments, lid 800 can be attached to a fence using conductive adhesive such as pressures sensitive adhesive, or PSA.

FIG. 9A illustrates another embodiment of the reduced thickness lid in the form of flexible lid 900. In the described embodiments, flexible lid 900 can be formed of flexible non-conductive material such as, for example, polyimide. As such flexible lid 900 can be etched in such a way that just as with substrate 102, various conductive structures can be formed on either a top or bottom surface. For example, as shown in FIG. 9A, flexible lid 900 includes top surface 902 on which is mounted a plurality of conductive strips 904. Conductive strips 904 can be formed of metal such as copper that can be connected to contact pads 906. At least some of conductive pads 906 can include center hole 908 that can be used in a soldering operation to secure flexible lid 900 to fence 106 as well as in some cases electrically couple the corresponding contact pad to chassis ground in a manner described below with reference to FIG. 9C.

In any case, pitch d₁ and d₂ between adjacent conductive strips (as well as contact pads 906) can be related to width w of each conductive strip in such a way that opening 910 defined by intersecting conductive strips and opening 912 defined by parallel conductive strips is less than the wavelength of the electromagnetic radiation emitted by any of the underlying components. In this way, the effectiveness of lid 900 as an RF shield remains essentially unaffected. Generally conductive strips 904 and conductive pads 906 are formed of conductive metal such as copper.

It should be noted that since flexible lid 900 is formed of non-conductive material, it is not necessary that insulating material be placed upon components having the potential of coming into contact with the bottom surface of flexible lid 900. However, in some cases it may be desirable to form a conductive path between conductive strip 904 and an underlying electronic component (such as providing an additional ground path). In order to form this electrical connection, opening 914 can be provided in appropriate locations along conductive strip 904.

FIG. 9B illustrates another embodiment where a substantially solid sheet of conductive material 920 (such as copper) is formed on top surface 902 of flexible lid 900. In this situation, conductive sheet 920 is electrically connected to contact pads 906 by way conductors 922 (and to each other) which in turn are connected to fence 106 in a manner shown in FIG. 9C.

However, in some embodiments, the effectiveness of lid 900 as an RF shield can be enhanced by coupling lid 900 to chassis ground. In particular, FIG. 9C shows a cross sectional view of a representative portion of lid 900 highlighting how conductive pad 906 can be used to form both a conductive path and be used to secure lid 900 to fence 106 using through hole 924 (also referred to as a via) formed through lid 900 in combination with contact pad 926 on bottom surface 928 of flexible lid 900. Lid 900 can be solder attached to fence 106 by applying solder 930 to conductive pad 906 some of which will migrate through via 924 and bond with fence 106. In this way, a conductive path between lid 900 and fence 106 can be formed allowing the associated conductive layer (conductive strips 904 or sheet 920) to become part of the chassis ground of the electronic device. In this way, the effectiveness of lid 900 as an RF shield can be improved.

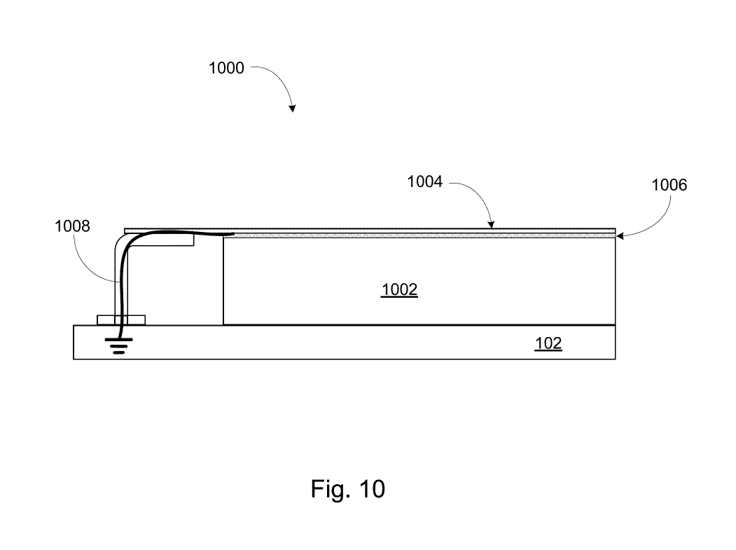

It should also be noted that by incorporating lid 900 as part of the chassis ground, the grounding for any components mounted to the PCB can also be improved. For example, as shown in FIG. 10, illustrating PCB system 1000 having component 1002 electrically coupled to grounded lid 1004 by way of conductive layer 1006. Conductive layer 1006 can be, for example, conductive adhesive that permits electrically conductive path 1008 to be formed between component 1002 and chassis ground by way of substrate 102.

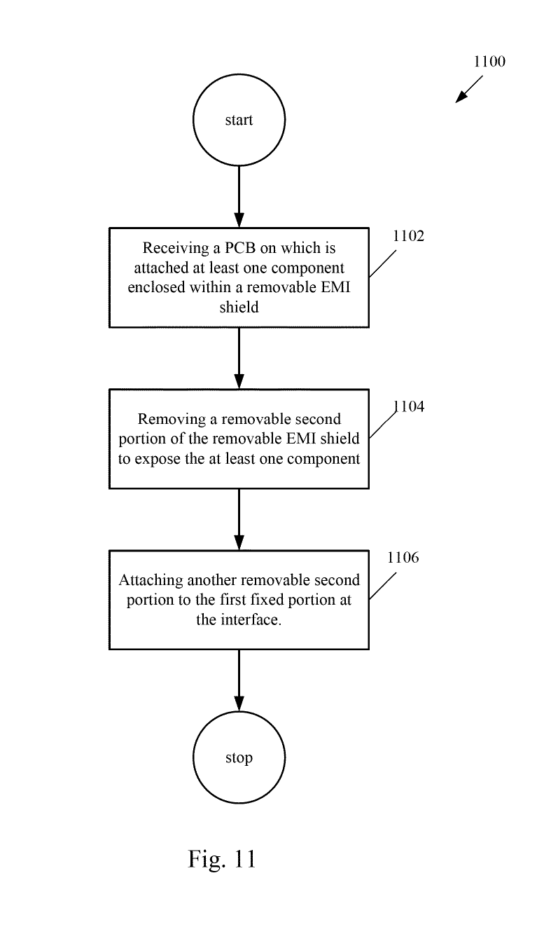

FIG. 11 shows a flowchart describing process 1100 in accordance with the described embodiments. Process 1100 can be performed by receiving at 1102 a printed circuit board on which at least one component requires rework, the at least one component being enclosed with an RF shield anchored to the PCB. In the described embodiment, the removable RF shield includes a first fixed portion anchored to the PCB attached to a removable second portion at an interface. At 1104, the removable second portion is detached from the first fixed portion leaving the first fixed portion attached to the PCB and exposing the at least one component requiring re-work. Once the component has been re-worked, the RF shield is reconstituted by providing another removable portion and re-attaching the other removable portion at the interface at 1106.

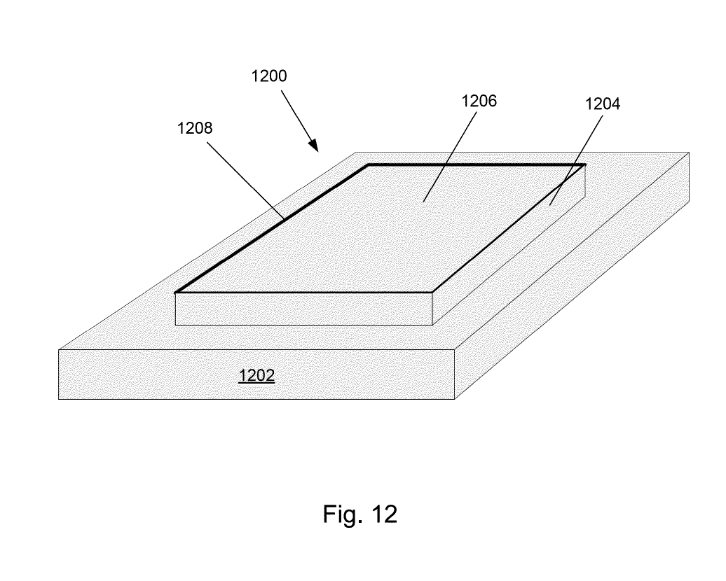

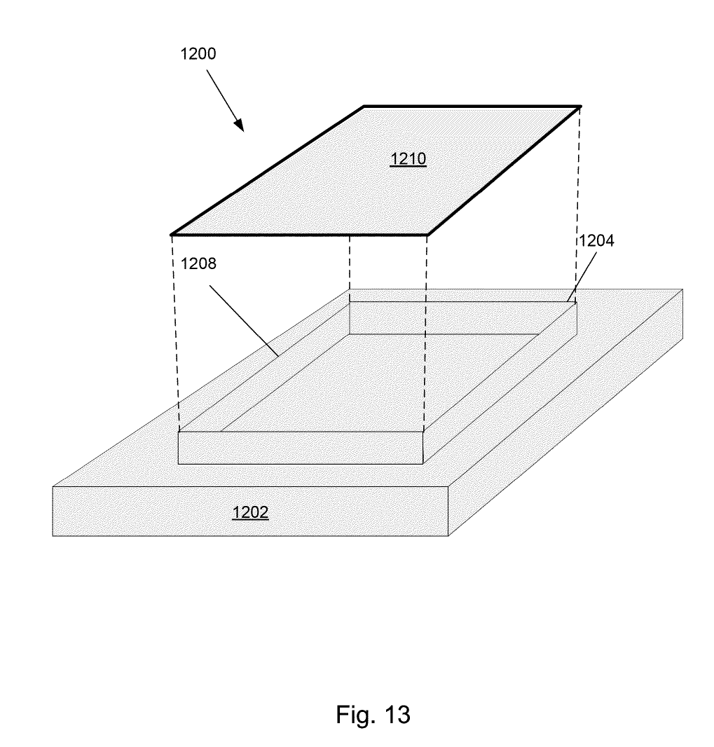

FIG. 12 shows a perspective view of a representative removable RF shield 1200 anchored to PCB 1202 in accordance with the described embodiments. Removable shield 1200 includes fence 1204 anchored to PCB 1202 and removable lid portion 1206 attached to fence 1204 at interface 1208. In order to expose a component within RF shield 1200 attached to PCB 1204, removable lid portion 1206 is removed as illustrated in FIG. 13 and replaced with another removable lid 1210. Once the component has been re-worked, the RF shield is reconstituted by attaching another removable lid 1210 to fence 1204. In one embodiment, fence 1204 and the other removable lid 1210 are welded together. In a particular implementation, the welding is carried out using a laser beam.

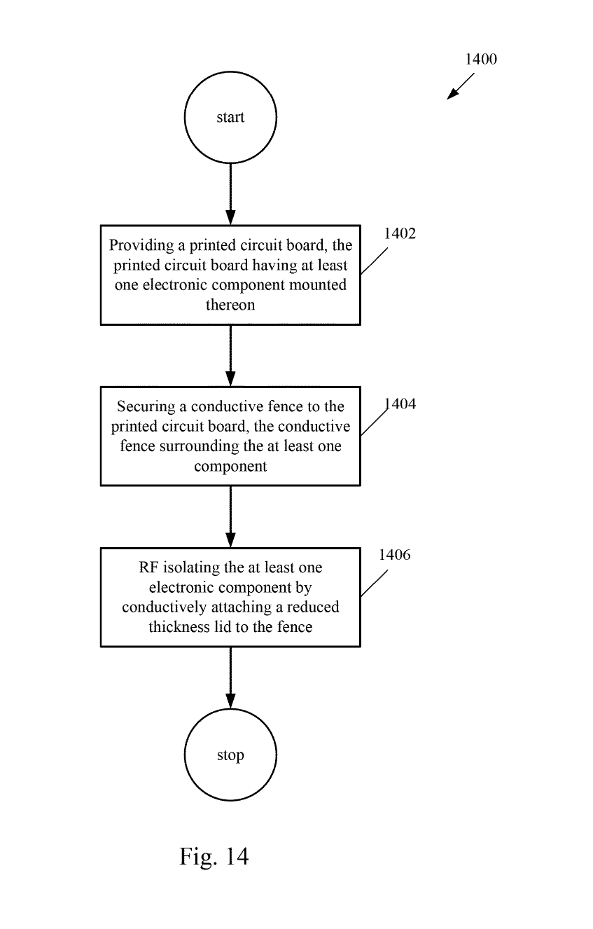

FIG. 14 shows a flowchart describing process 1400 in accordance with the described embodiments. Process 1400 can be performed by providing a printed circuit board, the printed circuit board having at least one electronic component mounted thereon at 1402. Next at 1404, securing a conductive fence to the printed circuit board, the conductive fence surrounding the at least one component. Next at 1406, RF isolating the at least one electronic component by conductively attaching a reduced thickness lid to the fence. In one embodiment, the reduced thickness lid comprising at least a layer of metal having a thickness in a range of about 0.009 millimeters to 0.050 millimeters, wherein a clearance between a bottom surface of the layer of metal and at the least one electronic component is within a range of 0.0 millimeters to about 0.010 millimeters.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line used to fabricate computer components such as computer housing formed of metal or plastic. The computer readable medium is any data storage device that can store data which can thereafter be read by a computer system. Examples of the computer readable medium include read-only memory, random-access memory, CD-ROMs, DVDs, magnetic tape, optical data storage devices, and carrier waves. The computer readable medium can also be distributed over network-coupled computer systems so that the computer readable code is stored and executed in a distributed fashion.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description. They are not intended to be exhaustive or to limit the invention to the precise forms disclosed. It will be apparent to one of ordinary skill in the art that many modifications and variations are possible in view of the above teachings.

The embodiments were chosen and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents.

What is claimed is:

1. An RF shield formed of RF opaque material that permits access to components on a printed circuit board (PCB), the RF shield attached to the PCB and enclosing a portion of the PCB on which is mounted at least one electronic component, the enclosed portion of the PCB being RF isolated, comprising:
a fence secured to the PCB; and
a reduced thickness lid conductively attached to the fence, the reduced thickness lid comprising:
at least a layer of metal having a thickness in a range of about 0.009 millimeters to 0.050 millimeters, wherein a clearance between a bottom surface of the layer of metal and at the least one electronic component is within a range of 0.0 millimeters to about 0.010 millimeters.

2. The RF shield as recited in claim 1, wherein the metal is stainless steel, and wherein the reduced thickness lid is conductively attached to the fence by a welding operation.

3. The RF shield as recited in claim 1, wherein the metal is aluminum, and wherein the reduced thickness lid is conductively attached to the fence by a soldering operation.

4. The RF shield as recited in claim 1, wherein the reduced thickness lid is conductively attached to the fence using a conductive adhesive, and wherein the conductive adhesive facilitates the removal of the reduced thickness lid without damaging the fence.

5. The RF shield as recited in claim 4, wherein the removable lid is removed from the fence by peeling away the lid from the fence to expose the at least one component mounted to the PCB.

6. The RF shield as recited in claim 5, wherein the at least one exposed component is subsequently RF isolated by:
placing a replacement lid on the fence, the replacement lid having a layer of conductive adhesive on a peripheral portion of the replacement lid corresponding to the fence; and
allowing the conductive adhesive to cure such that the replacement lid is conductively secured to the fence.

7. The RF shield as recited in claim 5, wherein the at least one exposed component is subsequently RF isolated using a laser to attach a replacement lid to the fence.

8. The RF shield as recited in claim 1, wherein the layer of metal includes a plurality of perforations each of which has an overall dimension that is less than a wavelength of the electromagnetic radiation emitted by the at least one enclosed component.

9. The RF shield as recited in claim 1, wherein the reduced thickness lid further comprises:
a flexible non-conducting substrate having a top surface and a bottom surface; and
at least one conductive pad on the top surface, the at least one conductive pad being electrically connected to the layer of metal in the form of a conductive strip, wherein the at least one conductive pad and the conductive strip are part of a conductive grid.

10. The RF shield as recited in claim 9, wherein the conductive grid is conductively attached to the fence such that the conductive grid is electrically connected to a chassis ground.

11. A method of assembly, comprising:
providing a printed circuit board, the printed circuit board having at least one electronic component mounted thereon;
securing a conductive fence to the printed circuit board, the conductive fence surrounding the at least one component; and
RF isolating the at least one electronic component by conductively attaching a reduced thickness lid to the fence, the reduced thickness lid comprising at least a layer of metal having a thickness in a range of about 0.009 millimeters to 0.050 millimeters, wherein a clearance between a bottom surface of the layer of metal and at the least one electronic component is within a range of 0.0 millimeters to about 0.010 millimeters.

12. The method as recited in claim 11, wherein the metal is stainless steel, and wherein the reduced thickness lid is conductively attached to the fence by a welding operation.

13. The method as recited in claim 11, wherein the metal is aluminum, and wherein the reduced thickness lid is conductively attached to the fence by a soldering operation.

14. The method as recited in claim 11, wherein the reduced thickness lid is conductively attached to the fence using a conductive adhesive, and wherein the conductive adhesive facilitates the removal of the reduced thickness lid without damaging the fence.

15. The method as recited in claim 11, wherein the reduced thickness lid further comprises:
a flexible non-conducting substrate having a top surface and a bottom surface; and
at least one conductive pad on the top surface, the at least one conductive pad being electrically connected to the layer of metal in the form of a conductive strip, wherein the at least one conductive pad and the conductive strip are part of a conductive grid.

16. The method as recited in claim 15, further comprising conductively attaching the conductive grid to the fence such that the conductive grid is electrically connected to a chassis ground.

17. The method as recited in claim 16, further comprising connecting the RF isolated component to the chassis ground by conductively attaching the RF isolated component to the conductive grid.

18. An EMI shield formed of RF opaque material that permits access to a component on a printed circuit board (PCB), comprising:
a first portion attached to the PCB; and
a removable top portion attached to the first portion at an interface, wherein the top portion is removable from the first portion to expose the component on the PCB.

19. The EMI shield as recited in claim 18, wherein the removable top portion is removable from the first portion by peeling away the top portion from the first portion.

20. The EMI shield as recited in claim 19, wherein the exposed component is subsequently enclosed within the EMI shield after the removal of the top portion by attaching and sealing a second top portion to the first portion at the interface.

21. The EMI shield as recited in claim 20, wherein the sealing is carried out by laser attaching the first portion and the second top portion at the interface.

22. A method comprising:
attaching a first portion of a shield assembly to a circuit board;
after the attaching, removing a second portion of the shield assembly from the first portion of the shield assembly; and
after the removing, coupling a new portion of the shield assembly to the first portion of the shield assembly.

23. The method of claim 22, wherein the coupling comprises laser welding.

24. The method of claim 22, wherein the removing comprises peeling the second portion away from the first portion.

25. The method of claim 22, wherein the removing comprises breaking a joint between the first portion and the second portion.

26. The method of claim 22, wherein:
the attaching comprises attaching the first portion of the shield assembly to the circuit board about an electronic component; and
the removing comprises exposing the electronic component for re-work.

27. The method of claim 22, wherein the attaching comprises soldering the first portion of the shield assembly to the circuit board.

28. An assembly comprising:
a first portion configured to be attached to a mounting surface;
a second portion removably coupled to the first portion; and
a third portion configured to be attached to the first portion once the second portion is removed for shielding a component on the mounting surface.

29. The assembly of claim 28, wherein:
the first portion comprises a top and at least one side extending from the top to a free side end;
the free side end of the at least one side is configured to be attached to the mounting surface;
the second portion is removably coupled to the top of the first portion; and
the third portion is configured to be attached to the top of the first portion once the second portion is removed.

30. The assembly of claim 29, wherein:
the top of the first portion comprises an opening therethrough;
the opening is covered by the second portion when the second portion is coupled to the first portion; and
the opening is exposed once the second portion is removed.

31. The assembly of claim 29, wherein:
the top of the first portion comprises an opening therethrough; and
the opening is covered by the third portion once the third portion is attached to the first portion.

32. The assembly of claim 29, wherein:
the top of the first portion comprises an opening therethrough; and
the opening exposes the component for re-work once the second portion is removed.

33. The assembly of claim 28, wherein the second portion is removably coupled to the first portion at an easily broken joint.

34. The assembly of claim 28, wherein the third portion is configured to be welded to the first portion.
